(19) United States
(12) Patent Application Publication
(10) Pub. No.: US 2018/0150233 A1
(43) Pub. Date: May 31, 2018

(54) STORAGE SYSTEM

(71) Applicant: HITACHI, LTD., Tokyo (JP)

(72) Inventors: Satoru HANZAWA, Tokyo (JP); Takashi CHIKUSA, Kanagawa (JP); Naoki MORITOKI, Tokyo (JP)

(73) Assignee: HITACHI, LTD., Tokyo (JP)

(21) Appl. No.: 15/578,360

(22) PCT Filed: Jun. 3, 2015
(86) PCT No.: PCT/JP2015/066069

§ 371 Date: Nov. 30, 2017

(51) Int. Cl. G06F 3/06; G06F 11/10; G11C 29/52

(52) U.S. Cl. CPC G06F 3/0607; G06F 3/0685; G11C 29/52; G06F 3/065; G06F 11/1068; G06F 3/0619

(57) ABSTRACT

A storage system according to an embodiment of the present invention includes a storage device and a storage controller having a memory chip with a magneto-resistant element as a memory element, a memory device having a memory controller for controlling the memory chip, and a processor. The processor may be configured to manage a storage are of the memory chip by dividing the storage area into a storage area used by the processor and a storage area not used by the processor. The processor may be configured to execute, in a periodic fashion, an update process of reading data stored in the storage area and writing the data back to the storage area.

### TECHNICAL FIELD

The present invention relates generally to a storage system.

### BACKGROUND ART

Storage devices primarily store data in nonvolatile memory devices such as hard disk drives (HDDs), but it is also possible to include semiconductor memory such as DRAM, and use this DRAM, for example, as a cache memory for temporarily storing write data from a host computer or for storing control information and the like used in storage controllers. The characteristics of DRAM however, are such that stored contents may be volatized without power being supplied, and periodic data write backs (refreshes) are necessary. Accordingly, in order to prevent the loss of content stored in the DRAM, countermeasures such as the use of batteries or the like to maintain data in the event of a power outage are necessary.

Recently, a type of memory that utilizes a magneto-resistant element (hereinafter referred to as “magnetic memory”) has become known. The characteristics of this magnetic memory are such that it is non-volatile and non-destructive readouts are possible, such that it is promising as a prospective replacement of DRAM. The information retention time of memory elements of magnetic memory, however, may be on the order of days or months depending on the characteristics of the memory element and the length of current application at write time. Accordingly, if long-term data retention is desired, some form of countermeasure may be necessary. Patent Document 1 discloses an invention related to magnetic memory in which, when the number of reads exceeds a predetermined number of times, data stored in the main memory read out and written back to the main memory (e.g., a refresh is performed).

### CITATION LIST

### Patent Literature

[Patent Document 1] Japanese Unexamined Patent Application Publication No. 2012-22726 A

### SUMMARY OF INVENTION

### Technical Problem

In memory, not all areas are always used at all times. There are times, for instance, when some areas are in use (e.g., information is stored), but other areas may be in an unused state. When the memory is in such a state, from the viewpoint of maintaining performance, it is not efficient to take measures for information retention with respect to the entire memory area. In the technique disclosed in Patent Document 1, there is no disclosure of selectively refreshing particular storage areas, and there is significant overhead with respect to refreshes.

### Solution to Problem

A storage system according to one embodiment of the present invention includes a storage device and a storage controller having a memory chip with a magneto-resistant element as a memory element, a memory device having a memory controller for controlling the memory chip, and a processor. The processor may be configured to manage a storage area of the memory chip by dividing the storage area into a storage area used by the processor and a storage area not used by the processor. The processor may be configured to execute, in a periodic fashion, an update process of rending data stored in the storage area and writing the data back to the storage area.

### Advantageous Effects of Invention

According to the present invention, it is possible to selectively increase the information retention time for a memory area in which necessary data is stored.

### BRIEF DESCRIPTION OF DRAWINGS

FIG. 1 is a hardware configuration diagram of a storage system.

FIG. 2 is a configuration diagram of a memory chip.

FIG. 3 is a diagram illustrating a representative operation of a semiconductor memory.

FIG. 4 is a timing chart of a read operation.

FIG. 5 is a timing chart of a write operation.

FIG. 6 is a timing chart of an update operation.

FIG. 7 is a command truth table of a memory chip.

FIG. 8 is a configuration diagram of a cache memory package.

FIG. 9 is a diagram illustrating an example of an area management table.

FIG. 10 is a diagram illustrating an example of slot management information.

FIG. 11 is a diagram illustrating an example of a retention queue.

FIG. 12 is a flowchart of a data write process to a slot.

FIG. 13 is a flowchart of a data verification process.

FIG. 14 is a flowchart of an update process executed by a memory controller.

FIG. 15 is a flowchart of a planned stop time.

### DESCRIPTION OF EMBODIMENT(S)

Hereinafter, embodiments of the present invention will be described with reference to the Figures. It should be noted that the embodiments described herein are not intended to limit the invention according to the claims, and it is to be understood that each of the elements and combinations thereof described with respect to the embodiments are not strictly necessary to implement the aspects of the present invention.

In addition, in the following description, there are cases where the explanation refers to a “program” as a subject for implementing an aspect of the invention, but in actuality the program is executed by a processor so that a predetermined processing operation may be carried out. However, in order to prevent the description from becoming redundant, aspects of the invention are referred to as being implemented with reference to a program as the subject. In addition, part or all of the program may be implemented using dedicated hardware. Also, various programs may be installed in each device by a program distribution server or a storage medium readable by a computer. The storage device may, for example, include an Integrated Circuit (IC) card, a Secure Digital (SD) card, a Digital Versatile Disk (DVD), or other storage apparatus.

### (1-1) Storage System Configuration

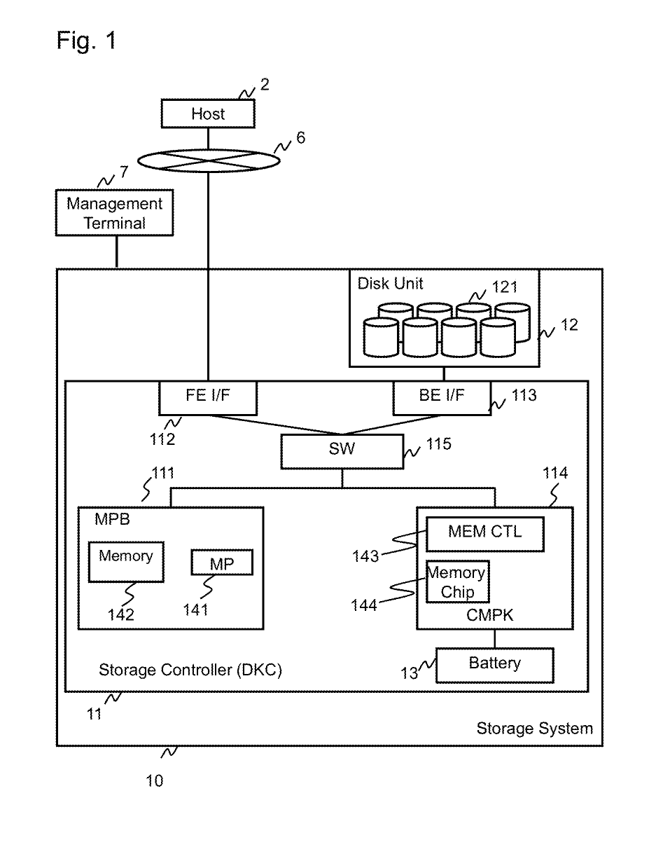

FIG. 1 illustrates a configuration of a storage system 10 according to an embodiment of the present invention. The storage system 10 may include a storage controller 11 (hereinafter sometimes abbreviated as “DKC”), a disk unit 12 having a plurality of drives 121, and a battery 13. The storage controller 11 may include an MPB 111 which is a processor board for executing control operations such as I/O processing and the like performed within the storage system 10, a front end interface 112 (FE I/F) which is a data transfer interface with a host 2, a back end interface 113 (BE I/F) which is a data transfer interface with the disk unit, and a cache memory package 114 (CMPK) for storing cache data, control data, and the like. The above components of the storage controller 11 may be interconnected to one another using a switch 115 (SW). The quantity of each component (MPB 111, FE I/F 112, BE I/F 113, CMPK 114) is not limited to the number deputed in FIG. 1. Configurations in which a plurality of one or more components are utilized to facilitate high availability and high performance of the storage system are also possible.

Each MPB 111 may include a processor 141 (also referred to as an MP) and a local memory 142 for storing a control program executed by the processor 141 and control information to be utilized by the control program. Read and write requests from the host 2 may be processed by the processor 141 executing a program stored in the local memory.

The CMPK 114 may include a memory device having a memory chip 144 (abbreviated as “chip” in the figures) and a memory controller 143 (MEMCTL) for controlling the memory chip 144. In the present embodiment, a magneto-resistive random access memory (MRAM) or STT-RAM using a magneto-resistive element as a memory element may be used for the memory chip 144 (sometimes referred to as “magnetic memory” with respect to the present embodiment). In embodiments, there may be a plurality of MEMCTL 143 and a plurality of memory chips 144. In the storage system 10 according to the present embodiment, the CMPK 114 may be used as a cache memory for temporarily storing write data and the like from the host 2. The CMPK 114 may also be utilized for storing control information used in the storage system 10.

The battery 13 may be configured to supply electric power to the CMPK 114 in the event of a failure such as a power outage. An external power source (not shown) may be connected to the storage system 10 in addition to the battery 13. During normal operation (when electric power is supplied from an external power supply) the storage system 10 may operate using electric power supplied from the external power supply. When the externally supplied power interrupted due to a power failure or the like, the CMPK 14 may use power supplied from the battery 13 to perform the operations necessary to maintain the data in the storage system 10. Note that configurations in which the battery may be mounted on the CMPK 114 are also possible.

The disk unit 12 may include a plurality of drives 121, and each drive 121 may primarily store write data from the host 2. The drives 121 may include storage devices that use magnetic storage mediums, such as an HDDs, for example. However, other storage devices such as solid state drives (SSDs) may also be used.

The FE I/F 112 may include an interface for communicating data with the host 2 via a SAN 6. The FE I/F 112 may include a DMA controller (DMAC) for transmitting write data from the host 2 to the CMPK 114 or transmitting data in the CMPK 114 to the host 2 based on an instruction from the MPU 141. Similar to the FE I/F 112, the BE I/F 113 may also include a DMAC for transmitting data in the CMPK 114 to the drives 121 or transmitting data from the drives 121 to the CMPK 114 based on an instruction from the MPU 141.

The switch (SW) 115 may be a component for interconnecting the MPB 111, the FE I/F 112, the BE I/F 113, and the CMPK 114, and may, for example, be a PCI-Express switch.

The SAN 6 may include a network used to transfer access requests (I/O requests) and read and write data accompanying access requests when the host 2 accesses (reads or writes) data of a storage area (storage volume) in the storage system 10. In the present embodiment, the SAN 6 may include a network configured using a fiber channel. However, configurations using another transmission medium such as Ethernet are also possible.

### (1-2) Memory Chip Configuration

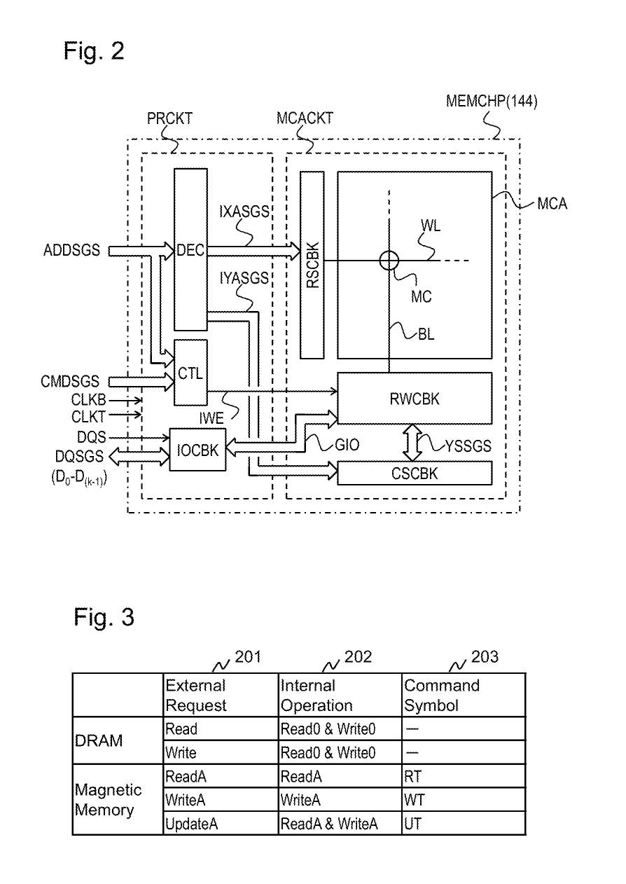

FIG. 2 is a configuration diagram of a memory chip 144 (MEMCHP) according to the present embodiment. The memory chip 144 may include a memory cell array circuit MCACKT and a peripheral circuit PRCKT.

The memory cell array circuit MCACKT may include a memory cell array MCA, a read/write circuit group RWCBK, a row selection circuit group RSCBK, and a column selection group CSCBK. The memory cell array MCA may have m×n memory cells MC arranged at intersections of a plurality (e.g., m) of word lines WL and a plurality (e.g., n) of bit lines BL.

The row selection circuit group RSCBK may be configured to activate one word line selected by the internal row address signal line group IXASGS (to be described later) from among the m word lines WL. Similarly, the column selection circuit group CSCBK may be configured to activate k (k≤n) bit lines selected by the internal column address signal line group IYASGS (to be described later) from among the n bit lines BL.

The memory cell MC may be magnetically resistant, and be configured to store information corresponding to its resistance value. In the present embodiment, for example, it may be defined such that information “1” may be stored when the magneto-resistance is in a low resistant state, and information “0” may be stored in a high resistant state. The read/write circuit group RWCBK may be provided between the memory cell array MCA and an internal global input/output line GIO (to be described later), and be configured to read stored information from the selected memory cell or write new information to the selected memory cell based on an internal write start signal IWE (to be described later).

The peripheral circuit PRCKT may include an address decoder DEC, a controller CTL, and an input/output circuit group IOCBK. The address decoder DEC may drive the internal row address signal line group IXASGS and the internal column address signal line group IYASGS based on the address signal group ADDSGS input from outside of the memory chip 144.

The controller CTL may generate a control signal utilized for chip internal operation, such as the above-described internal write start signal IWE, based on the address signal group ADDSGS and the command signal group CMDSGS. The input/output circuit group IOCBK may exchange storage information between a data strobe signal DQS, a data signal group DQSGS (D₀ to Dₖ₋₁), and the above-described internal global input/output line GIO. Note that the operations within the memory chip 114 are performed in synchronization with the system clocks CLKT and CLKB.

### (1-3) Memory Chip Read Operation and Write Operation

FIG. 3 illustrates a representative operation of a semiconductor memory. Herein, in order to explain the difference between the two semiconductor memories of the DRAM and the magnetic memory, a comparison is shown between a request 201 from external to the semiconductor memory and an internal operation performed within the semiconductor memory chip in response to the request 201.

As is widely known, DRAM has memory cells arranged in a matrix at intersections of a plurality of word lines and a plurality of bit lines. These memory cells may be composed of a selection transistor and a capacitor. The capacitor may serve as a memory element and store 1-bit information by accumulating electric charge.

Next, a read operation of the DRAM will be described herein. When the DRAM enters read mode in response to an external request, the selection transistor in the memory cell located at the intersection of the selected word line and bit line in the DRAM chip becomes conductive, such that the accumulated charge is divided based on the load capacitance of the bit line and the capacitor in the memory cell. As a result, a small potential difference is generated in the corresponding bit line. This small potential difference is identified by the sense amplifier, such that the reading operation for the desired 1-bit information may be performed.

In the 1-bit information read operation, however, as a result of the previously performed capacitance division, the charge accumulated in the capacitor of the memory cell is reduced in comparison with the charge prior to the read operation. An operation such as this in which a state change of the memory element accompanies the 1-bit information read operation is referred to as a destructive read operation. Accordingly, it is necessary to restore the charge amount in the memory cell to a value sufficient to retain the 1-bit information. That is, a write operation of the same information that was previously read may be performed to restore the accumulated charge amount to a sufficient value. In summary of the above operation, when a read request is received from external to the DRAM, a 1-bit information write operation (Write 0) may be performed inside the DRAM following the 1-bit information read operation (Read 0).

In the DRAM write operation, there may be a slight difference in the input timing of the command signal, but similar to the above-described operation, a 1-bit information write operation (Write 0) may be performed subsequently to the 1-bit information read operation (Read 0). Herein, the 1-bit information read operation (Read 0) is performed in order to maintain the state of the memory element located at the intersection of the selected word line and the unselected bit line in the memory cell. That is, in this memory cell, it is necessary to perform a write operation (Write 0) of the same information after a 1-bit information read operation (Read 0).

Next, a write operation and a read operation of the magnetic memory will be described herein. The memory cells of the magnetic memory may be composed of a selection transistor and magneto-resistance. This magneto-resistance may be used for a memory element. The resistance value may change in accordance with the magnitude and direction of the applied current used in the 1-bit information write operation. However, even when a voltage less than the threshold value set based on the characteristics of the magneto-resistance is applied or the power supplied to the magnetic memory chip is interrupted, this resistance value may be maintained. Accordingly, in the 1-bit information read operation, a voltage less than a threshold value may be applied to the magneto-resistance, and the magnitude of the current flowing may be ascertained based on the resistance value. In this way, as the physical phenomenon responsible for storing the 1-bit information is maintained, the 1-bit information read operation of the magnetic memory may be considered to be a non-destructive read operation.

By leveraging the nondestructive nature of such a read operation, read operations of the magnetic memory may be completed with a 1-bit information read operation (Read A). That is, for read operations of the magnetic memory, it is unnecessary to perform 1-bit information write operations as in DRAM. Similarly, write operations to the magnetic memory can also be completed with only a 1-bit information write operation for the same reason.

The document “Time-Resolved Reversal of Spin Transfer Switching in a Nanomagnet” (Koch et al, Physical Review Letters 92, 088302, 2004) describes how the characteristics of the magneto-resistance used for memory cells of magnetic memory are such that write operation times (length of time that electric current is applied to the magneto-resistance) are increased in accordance with the information retention time. Here, the information retention time refers to the maximum value of the time during which the information stored in the storage area can be maintained. When a time period longer than the information retention time elapses after information is stored in the storage area, there is a possibility that the content of the information stored in the storage area may change.

For magnetic memories configured to shorten write operation times for high performance, the information retention time may be reduced. For example, in some configurations the information retention time may be on the order of days or months. The storage system 10 according to the present embodiment may be configured to primarily use the magnetic memory as the cache memory of the storage controller 11. In the event that the information retention time of the magnetic memory is on the order of days or months, the information of the magnetic memory may be lost before the storage controller 11 re-accesses the information stored in the magnetic memory. This may correspond to losing user-stored data. On the other hand, lengthening the write operation time of the magnetic memory may lead to a decrease in access performance; accordingly, when considering performance, short write operation times may be desirable.

In order to solve this problem, the storage system 10 according to the present embodiment primarily utilizes two functions described herein. The first function is a function by which an external device such as the storage controller 11 can select the write operation time at the time of writing data to the memory chip 144. When it is desired to lengthen the information retention time of particular data, the storage controller 11 (or MEMCTL 143) may instruct the memory chip 144 to perform a write operation with a lengthened write time. In response to receiving the instruction, the memory chip 144 may write the data using a long write operation time. In contrast, when it is desired to prioritize access performance in favor of the information retention time, the storage controller 11 (or the MEMCTL 143) may instruct the memory chip 144 to write data with a shorter write operation time, and the memory chip 144 may perform a write operation with a short write operation time. Using this function, it is possible to selectively perform write operations with long write operation times such that decreases in access performance can be avoided.

The second function is a function to periodically read out the data stored in the memory chip 144, and write the data back to the same memory cell again. Using this function, even if data is written with a short write operation time, the risk of data loss can be reduced.

Therefore, in addition to the operation mode of Read A and Write A, the memory chip 144 according to the present embodiment may include an operation mode of Update A. Update A may be an operation mode for performing a read operation Read A and a write operation Write A for rewriting the read information back to the same memory cell. Note that in this specification, the operation of rewriting the information read out by the read operation Read A to the same memory cell is referred to as an “update operation.” The command symbol 203 of FIG. 3 is an abbreviation of a command used when externally instructing the memory chip 144 to perform read operation Read A, write operation Write A, and update operation Update A.

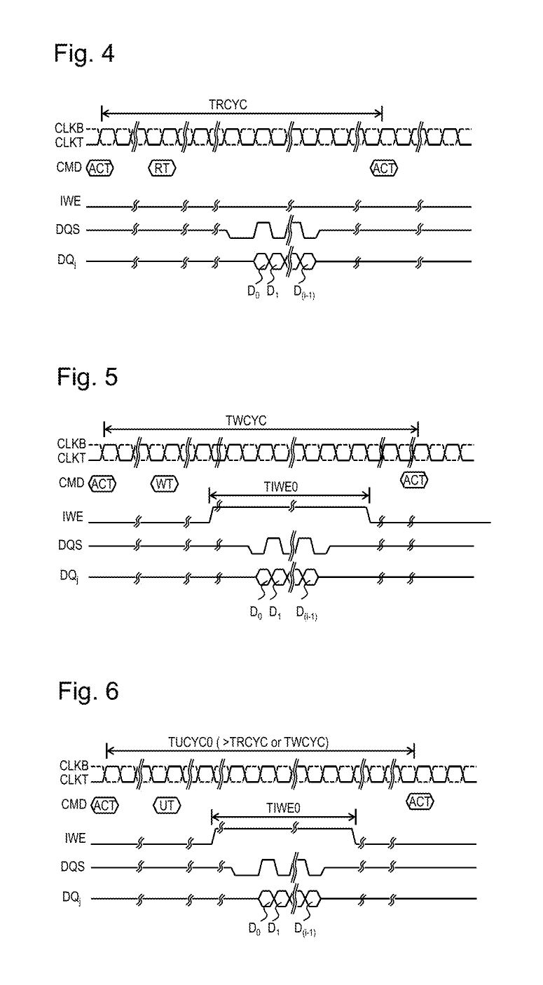

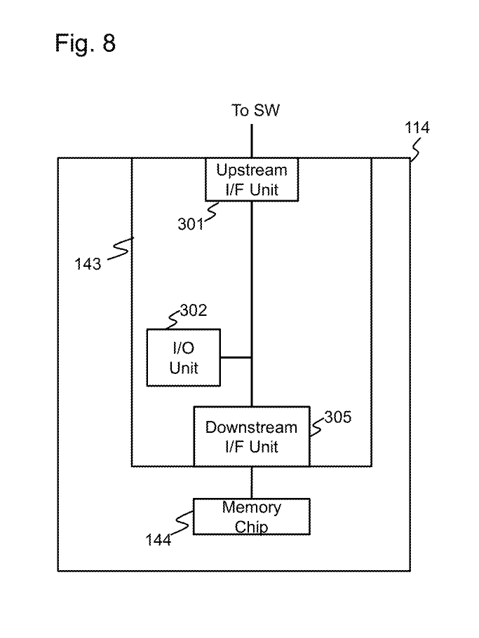

FIG. 4 is a timing chart of a read operation performed by the memory chip 144 according to the present embodiment. This operation may correspond to the read operation Read A described in FIG. 8. FIG. 4 illustrates an example of a read operation with a burst length i.

First, an active command ACT may be input from outside (MEMCTL) of the memory chip 144 to the controller CTL. Then, after a predetermined clock cycle time elapses, the read command RT may be input. While the internal write start signal IWE is kept inactive (in this case, logical value 0), the stored information in the memory cell MC may be read out to the data pin DQᵢ in synchronization with the data strobe DQS signal. Subsequently, the memory chip 144 may return to a standby state within a predetermined clock cycle time such that it can receive subsequent active commands ACT. Here, when receiving consecutive active commands, the shortest allowable interval is referred to as an operation cycle time. In FIG. 4, the operation cycle time at read time is set to TRCYC.

FIG. 5 illustrates a timing chart of a write operation performed in the memory chip 144 according to the present embodiment. This operation may substantially correspond to the write operation Write A described in FIG. 3. FIG. 5 illustrates an example of a write operation with a burst length i.

First, an active command ACT may be input from outside (MEMCTL 143) of the memory chip 144 to the controller CTL. Subsequently, after a predetermined clock cycle time, a write command WT may be input. In response to the input of the command WT, the internal write start signal IWE may be transitioned to an active state and its logical value may be held at 1 only for the duration of the internal write start time TIEW 0, such that information input to the data pin DQᵢ from the outside may be written to the memory cell MC. Thereafter, the memory chip 144 may return to a standby state within a predetermined clock cycle time such that it can receive subsequent active commands ACT.

Although FIG. 5 illustrates an example in which the internal write start signal IWE may be held at a value of 1 only for the duration of the internal write start time TIWE 0, the memory chip 144 according to the present embodiment may have 4 typos of internal write start times (TIWE 0, TIWE 1, TIWE 2, TIWE 3) configured to be selectable (according to the relationship TIWE 0<TIWE 1<TIWE 2<TIWE 3). The internal write start time selection method will be described later herein. In addition, the operation cycle time TWCYC at the time of the write operation may become shorter as the internal write start time (TIWE 0, TIWE 1, TIWE 2, TIWE 3) becomes shorter, and the longer the internal write start time, the longer the TWCYC. However, when compatibility with the existing DRAM is considered, it may be desirable that the TWCYC be equal to or shorter than the write operation cycle time of the existing DRAM at least when the internal write start time is TIWE 0.

FIG. 6 is a timing chart of an update operation performed in the memory chip 144 according to the present embodiment. This operation may correspond to the above-described update operation Update A, and FIG. 6 illustrates an update operation with a burst length i as an example. First, an active command ACT may be input, and a command UT (update command) may be input after a predetermined clock cycle time. In response to the input of the command UT, the internal write start signal IWE may be transitioned to an active state and its logical value may be held at 1 only for the duration of the internal write start time TIWE 0, such that the write operation Write A may be performed following the read operation Read A.

In this write operation Write A, the stored information held in the buffer of the read/write circuit group RWCBK may be written after being read out by the read operation Read A. Subsequently, the memory chip 114 may return to the standby state within a predetermined clock cycle time such that it can receive subsequent active commands ACT. After receiving an active command ACT corresponding to the update operation, the shortest allowable interval before a subsequent active command can be received is referred to as an update operation cycle time. FIG. 6 explicitly indicates an update operation cycle time TUCYC 0. The value of TUCYC 0 may be greater than the operation cycle time TRCYC or TWCYC illustrated in FIG. 4 by an amount corresponding to the write operation Write A.

With respect to FIG. 6, as in FIG. 5, an example is shown in which the internal write start signal IWE is held at 1 only for the duration of the internal write start time TIWE 0. However, the memory chip 144 of the present embodiment may include 4 types of internal write start times (TIWE 0, TIWE 1, TIWE 2, TIWE 3) configured to be selectable for the update operation (according to the relationship TIWE 0<TIWE 1<TIWE 2<TIWE 3). The internal write start time selection method will be described later herein.

### (1-4) Command(s)

Nest, external commands input to the memory chip 144 in order to execute the above-described update operation will be described. In the memory chip 144 of the present embodiment, the chip interface may be shared with the DDR specification used for DRAM to the extent possible. This is because, as the majority of magneto memories such as MRAM are being researched and developed as successor memories for existing DRAM, it is more suitable to replace an existing DRAM if the existing DRAM and chip interface are common. However, as the above update operation (Update A) is an operation mode that is not supported by existing DRAM, a new update command may be added to the DDR specification to configure it to support the update operation.

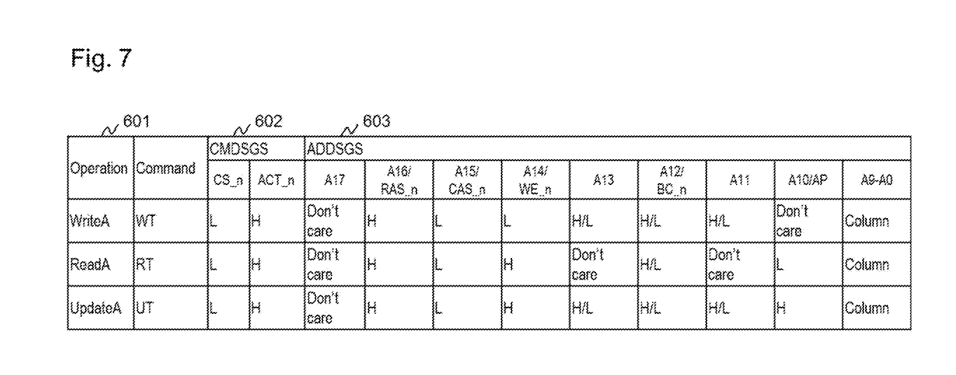

FIG. 7 illustrates a command truth table for a read command RT, a write command WT, and an update command UT in the memory chip 144 of the present embodiment. In this Figure, the names of each respective pin conforms to the specifications of DDR4 SDRAM.

The chip select signal CS_n and the activation command signal ACT_n 602 may be components of the command signal group CMDSGS of FIG. 2. Also, address signals A0 to A17 603 may be components of address signal group ADDSGS of FIG. 2. Among these, the address signal A16 may also serve as an RAS_n signal, the address signal A15 may also serve as a CAS_n signal, the address signal A14 may also serve as a WE_n signal, the address signal A12 may also serve as BC_n signal, and the address signal A10 may also serve as an AP signal.

In the memory chip 144 of the present embodiment, the pins A11 and A13 may be used for designating the internal write start time. Also, unnecessary A10 pins (AP: Auto-Precharge) may be used for identification of commands in the magnetic memory.

In the memory chip 144 of the present embodiment, the write command WT may be defined as a state in which the input to the A14 (/WE) pin of the memory chip 144 is low (L). When A14 (/WE)=L, the memory chip 144 may perform a write operation. At this time, the memory chip 141 may determine the internal write start time (write operation time) based on the combination of the input signals to the A11 and A13 pins as follows.
Write operation time A (internal write start time TIWE 0): (A13, A11)=(L,L)
Write operation time B (internal write start time TIWE 1): (A13, A11)=(L,H)
Write operation time C (internal write start time TIWE 2): (A13, A11)=(H,L)
Write operation time D (internal write start time TIWE 3): (A13, A11)=(H,H)

It should be noted that A, B, C, and D are described by the Relationship A<B<C<D, similar to the internal write start time.

Also, the read command RT may be defined as a state in which the input to the A14 (/WE) pin is high (H) and the input to the A10 pin is low. When the inputs to the A14 (/WE) and A10 pins are in this state, the memory chip 144 may perform a read operation.

Furthermore, the update command UT may be defined as a state in which the input to the A14 (/WE) pin is high and the input to the A10 pin is high. When the inputs to the A14 (/WE) pin and A10 pin are in this state, the memory chip 144 may perform the update process. Similar to the case of the write operation, the memory chip 144 may determine the write operation time based on the combination of the input signals to the pins A11 and A13.

It may be desirable to use mode “A” of the write operation time for writing data that is allowed to have short information retention times, or data that is frequently updated. Conversely, it may be desirable to use mode “D” of the write operation for writing data that is not frequently updated or data that requires long-term information retention.

Although an example was described herein in which four types of write operation times can be designated for the memory chip 144, write operation times beyond the four types described herein may also be specified. For instance, by using the undefined A17 in the DRAM, it may be possible to configure 8 types of write operation times to be selectable.

By defining the commands in this manner, the memory chip 144 can leverage the existing pins used in the DRAM. Accordingly, it may be possible to reduce hardware mounting costs.

It should be noted that the method of defining the commands is not limited to the method described above. Other implementation methods beyond those described above are also possible. For example, as an alternative method, assigning unused pins which are in a non-connected state in the existing DRAM to control signals for exchanging update commands may also be possible. Those signals may also correspond to the constituent elements of the command signal group CMDSGS illustrated in FIG. 2. In the event that such a method is utilized, it may be possible to reduce implementation costs while maintaining compatibility with the DRAM.

As another method, it may be possible to physically modify the chip interface of the existing DRAM. For example, a control signal pin for exchanging update commands may be added to the memory chip 144.

### (1-5) Cache Memory Package Configuration

Subsequently, the configuration of the CMPK 114 will be described with reference to FIG. 8. The CMPK 114 may include a memory controller (MEMCTL) 143 and a memory chip 144. Note that while there may be a plurality of MEMCTLs 143 or a plurality of memory chips 144 (or both), the following description primarily makes reference to an example in which one MEMCTL 143 and one memory chip 144 exist in the CMPK 114. Also, the method of mounting the memory chip 144 on the CMPK 114 is not limited to a particular method. For example, one or more memory chips 144 may be directly mounted on the substrate of the CMPK 114. Alternatively, one or more memory chips 144 may include a memory module such as a known DIMM (Dual Inline Memory Module), such that the memory chip 144 may be mounted on the CMPK 114 by connecting the memory module to a socket provided on the substrate of the CMPK 114.

The MEMCTL 143 may include the functional blocks of an upstream I/F unit 301, an I/O unit 302, and a downstream I/F unit 305. Each functional block may be implemented by hardware such as an Application Specific Integrated Circuit (ASIC). However, it is also possible to implement a plurality of functional blocks as a single ASIC.

Also, it is not necessary for all the functions to be implemented by hardware. For example, instead of providing the hardware of the I/O unit 302, a processor and a memory may be provided in the MEMCTL 143, and a predetermined program may be executed by the processor so that the processor functions as the I/O unit 302.

The upstream I/F unit 301 may include an interface for connecting the MEMCTL 143 to the SW 115 of the storage controller 11. Conversely, the downstream I/F unit 305 may include an interface for connecting the MEMCTL 143 and the memory chip 144.

The I/O unit 302 may include a functional block configured to read data from the memory chip 144 based on an access request from the MP141 received via the SW115 and the upstream I/F unit 301, or perform control operations to write data to the memory chip 144. In addition, the I/O unit 302 may include functionality for generating an error correcting code (ECC) and performing error detection and error correction using the ECC.

When the I/O unit 302 receives a write instruction and write target data from an external device via the upstream I/F unit 301, the I/O unit 302 may generate an error correcting code (ECC) from the write target data, and attach it to the write target data. Subsequently, the I/O unit 302 may write the write target data to which the ECC has been attached to the memory chip 114. Upon writing to the memory chip 144, the I/O unit 302 may then issue a write command WT described above to the memory chip 144.

Conversely, when the I/O unit 302 receives a read instruction from an external device via the upstream I/F unit 301, the I/O unit 302 may read the data with the attached ECC from the memory chip 144. When reading from the memory chip 144, the read command RT described above may be utilized. After reading the data with the attached ECC from the memory chip 144, the I/O unit 302 may perform error detection using the ECC (hereinafter referred to as an “ECC check”). More particularly, an ECC may be calculated from the read data, and the calculated ECC and the ECC attached to the data may be compared with each other to check whether any errors are present in the data.

In the event that the calculated ECC does not match the ECC attached to the data, it may be determined that an error is present in the data. In such a case, the I/O unit 302 may perform data correction using the ECC, and return the corrected data to the request source (for example, an external device as the MP 141) via the upstream I/F unit 301.

It should be noted that although the ECC is attached to the data and stored in the memory chip 144, the data and the ECC may not necessarily be stored adjacent to each other. For example, in a configuration in which the CMPK 114 has a plurality of memory chips 144 (for instance a number “n” memory chips) and externally received write data is stored in a distributed fashion in the plurality of memory chips 144, data may be written to (n−1) memory chips 144, and an ECC generated from the data stored in the (n−1) memory chips 144 may be stored in a separate memory chip 144.

### (2-1) Data Management in the Storage Controller

Next, processing performed by the storage controller according to the present embodiment will be described. First, the contents of the primary programs executed by the MP 141 of the storage system 10 of the present embodiment will be described. In the MP 141, an I/O program, an initialization program, a data verification program, and a stop program may be executed. However, execution of other programs beyond these is also possible. These programs may be stored in the local memory 142.

An I/O program may be executed when the storage system 10 receives an I/O request from the host 2. If the I/O request is a read request, data stored in an area of the drive 121 or the CMPK 114 may be read and returned to the host 2. If the I/O request is a write request, the write data received from the host 2 may be stored in an area of the drive 121 or the CMPK 114.

An initialization program may include a program for creating management information and a data structure for use by the storage system 10 in the local memory 142 or the CMPK 114 at start-up of the storage system 10.

A data verification program may include a program for executing processing corresponding to the second function described above. A stop program may be executed when the storage system 10 performs a planned shutdown. Details of each program will be described later.

Next, a method in which each component external to the CMPK 114 (for example, MP 141 or DMAC) performs data access to the CMPK 114 (that is, the memory chip 144) will be described. The storage system 10 of the present embodiment is configured such that, when the MP 141 or the DMAC accesses an area of a predetermined address (e.g., address A) of the memory chip 144, an instruction designating the address A is issued to the CMPK 114 so that it may be accessed. In the case of writing data to the memory chip 144 a write instruction may be issued, in the case of reading data a read instruction may be issued, and when an update process is instructed an update instruction may be issued.

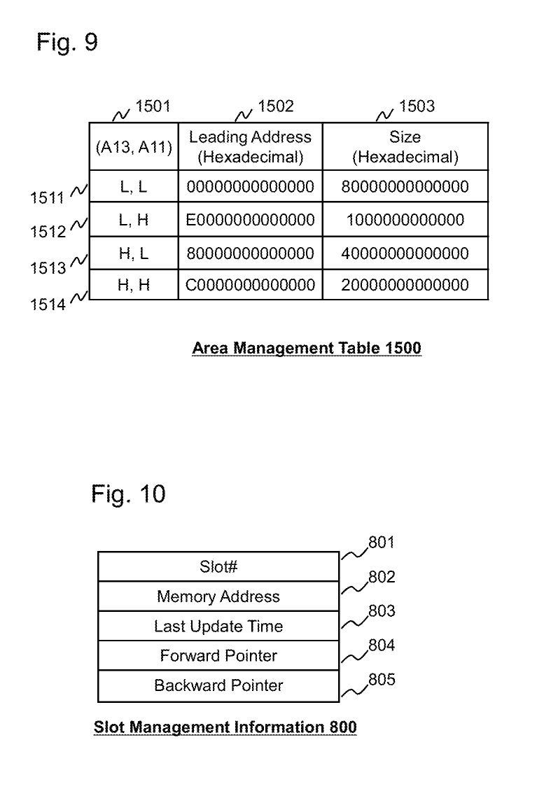

In addition, when performing a write process or an update process, it is necessary to notify the CMPK 114 (memory chip 144) of the write operation time. Although various methods can be utilized to provide notification of the write operation time, in the present embodiment, a method of providing notification of the write operation time by using the address of the write target area (an area on the memory chip 144) will be described. FIG. 9 depicts an example of an area management table 1500 for managing the relationship between the memory area of the CMPK 144 and the write operation time.

In the area management table 1500, the area specified by the leading address 1502 and the size 1503 indicates the storage area of the memory chip 144 accessible for each component of the storage controller 11. Column 1501 (A14, A11) indicates the state of the input signal to the A13 pin and the A11 pin of the memory chip 144 when data is written to this area.

For example, the leading row (row 1511) of FIG. 9 will be described. In this row, when writing to the area corresponding to the range of addresses 00000000000000H to 7FFFFFFFFFFFFFH, the state of the input signal to the A13 and the A11 pin of the memory chip 144 may be (L,L); that is, indicate that the write operation time is “A.”

The I/O unit 302 of the CMPK 114 may retain the area management table 1500. When the I/O unit 302 receives an external write instruction (e.g., from the MP 141, the DMAC or the like), the I/O unit 302 may determine the state of the signal to be input to the A13 pin and the A11 pin by comparing the write target address included in the write instruction with the range specified by the leading address 1502 and the size 1503 of the area management table 1500. For instance, when a write instruction for address 90000000000000H is received, this address may be included in the range of the third row (line 1513) of the area management table 1500 depicted in FIG. 9. Accordingly, when the I/O unit 302 performs a write to the memory chip 144, the signal to be input to the A13 pin and the A11 pin of the memory chip 144 may be determined to be (H,L).

A notification of the information registered in the area management table 1500 may be provided by the MP 141 that executes the initialization program to the CMPK 114 at initialization time of the storage system 10. The CMPK 114 may receive the notification from the MP 141 and register the information in the area management table 1500 retained by the I/O unit 302.

In addition, the relationship between the write operation time and the memory address may be configured to be predetermined (e.g., information regarding the relationship between the write operation time and the memory address is embedded in the program executed in the MP 141), or modifiable from the management terminal 7 external to the storage system 10.

In contrast, the MP 141 may manage the storage space of the CMPK 114 (memory chip 144) of each “slot,” or portion of a predetermined size, (e.g., 1 megabyte) on an individual basis. Managing by the MP 141 may include assigning a unique identification number to each slot. This identification number may be referred to as a “slot number” (also referred to herein as a slot#). For each slot, the MP 141 may create information necessary for managing that particular slot. This information may be referred to as slot management information.

FIG. 10 illustrates an example of the slot management information 800. Information regarding one slot may be managed by one set of slot management information 800. The slot management information 800 may include a slot# 801, a memory address 802, a last update time 803, a forward pointer 804, and a backward pointer 805. The slot number may be stored in the slot# 801, and the leading address of the area on the memory chip 144 corresponding to the slot managed by the slot management information 800 may be stored in the memory address 802. Information regarding the most recent date and time when a write or update process to the slot was performed may be stored in the last update time 803.

As described above, in the storage system 10 of the present embodiment, the write operation time may vary depending on the address of the memory chip 144. Accordingly, the MP 141 may have four types of queues in order to manage each write operation time for each slot; that is, a short-retention queue, a standard-retention queue, a medium-retention queue, and a long-retention queue. These four types of queues may be collectively revered to as “retention queues.”

The short-retention queue may include a queue for managing slots having the shortest write operation times (e.g., slots for write operation time A). More particularly, each slot managed by the short-retention queue may be a memory area in which signals (L,L) are input to the A13 and A11 pins of the memory chip 144 at the time of a write operation (or an update operation). Hereinafter, slots managed by the short-retention queue may be referred to as “short-retention slots.”

The standard-retention queue may include a queue for managing slots with the next shortest writing operation time (e.g., slots for write operation time B). For slots managed by the standard-retention queue, signals of (L,H) may be input to pins A13 and A11 of the memory chip 144 during write operations (or update operations). The medium-retention queue may include a queue for managing slots having the next shortest write operation times (e.g., slots for write operation time C). For slots managed by the medium-retention queue, signals of (H,L) may be input to pins A13 and A11 of the memory chip 144 during write operations (or update operations). The long-retention queue may include a queue for managing slots with the longest write operation times (slots for write operation time D). For slots managed by the long-retention queue, signals of (H,H) may be input to pins A13 and A11 of the memory chip 144 during write operations.

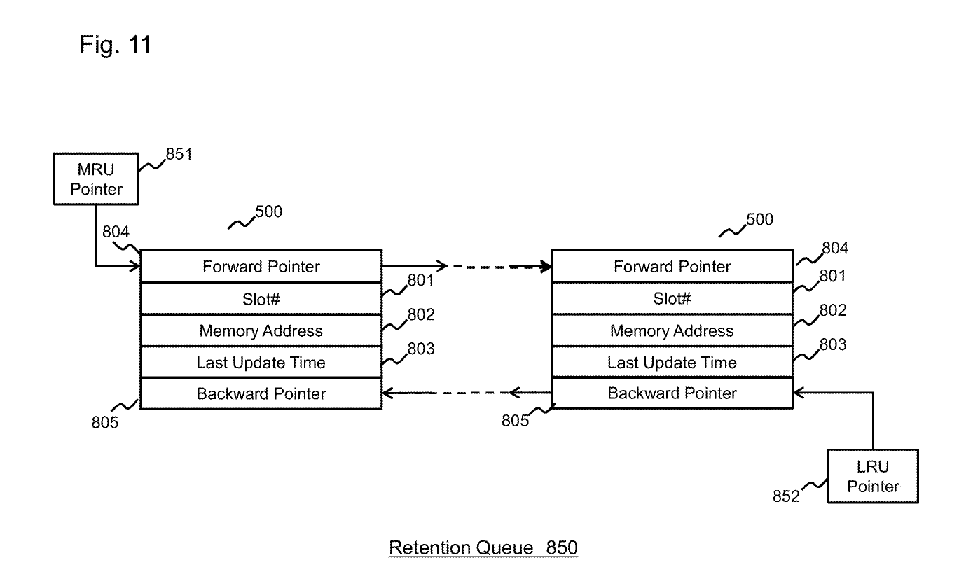

FIG. 11 illustrates the structure of a retention queue. Each of the short-retention queue, the standard-retention queue, the medium-retention queue, and the long-retention queue may have the same structure. In the following, a case in which the retention queue 850 of FIG. 11 is a short-retention queue will be described. Among the short-retention slots, the slot management information 800 of the slot that has been most recently written to or updated (slot management information 800 of the slot that has the most recent last update time 803) may be connected to the MRU pointer 851 of the retention queue. Also, a pointer to the next slot management information 800 (slot management information 800 of the slot that has the second most recent last update time 803) may be stored in the forward pointer 804 of the slot management information 800 connected to the MRU pointer 851. The slot management information 800 of the slot with the oldest last update time 803 may be connected to the LRU pointer 852. A pointer in the slot management information 800 of the slot with the second oldest last update time 803 may be stored in the backward pointer 805 of this slot. It should be noted that in the present description, the slot management information 800 connected to the MRU pointer is referred to as “slot management information 800 located at the tail end of the queue.” The slot management information 800 connected to the LRU pointer 852 is referred to as “slot management information 800 located at the head of the queue.”

In addition, the MP 141 may include four additional types of queues: a short-retention idle queue, a standard-retention idle queue, a medium-retention idle queue, and a long-retention idle queue. The structure of those queues may be substantially similar to that of the retention queues shown in FIG. 11. In an initial state, the slot management information 800 of each slot may be connected to any one of the short-retention idle queue, the standard-retention idle queue, the medium-retention idle queue, or the long-retention idle queue. The slot management information 800 of the short-retention slot may be connected to the short-retention idle queue in an initial state. Herein, the slot management information 800 of the standard-retention slot, the medium-retention slot, and the long-retention slot may be respectively connected to the standard-retention idle queue, the medium-retention idle queue, and the long-retention idle queue.

The MP 141 may also manage a queue called an error queue. The error queue may include a queue for managing slots in which errors (uncorrectable errors) occurred as a result of writing to that particular slot. The structure of the error queue may be substantially similar to that of the retention queues illustrated in FIG. 11.

The MP 141 may create slot management information for each slot at the time of initialization (e.g., start-up) of the storage system 10. Subsequently, the slot management information of the slot with the write operation time A may be connected to the short-retention idle queue. For example, when the relationship between the memory address and the write operation time is determined as shown in FIG. 9, slots in which the memory address (the memory address 802 of the slot management information 800) corresponds to the range of 00000000000000H to 7FFFFFFFFFFFFFH may be determined to be slots for the write operation time A.

Similarly, the slot management information of slots with write operation time B may be connected to the standard-retention idle queue. The slot management information of slots with write operation time C may be connected to the medium-retention idle queue. The slot management information of slots with write operation time D may be connected to the long-retention idle queue.

The retention queue, the retention idle queue, the error queue, and the slot management information connected to these queues may be stored in a specific area of the CMPK 114 (memory chip 144). This area may not be managed as slot management information.

Note that the slot management information, the retention queue, the retention idle queue, and the error queue may serve as management information provided for use as part of a data verification process to be described later herein. The MP 141 may include other management information used to facilitate management of the memory area of the memory chip 144. For instance, when the storage system 10 uses the memory area of the memory chip 144 as a cache area for storing write data from the host 2, information for managing the state of the data (as indicated in the drive 121) stored in the memory area may also be necessary. Such information may be prepared as management information different from the slot management information, the retention queue, and the like.

### (2-2) Write Processing

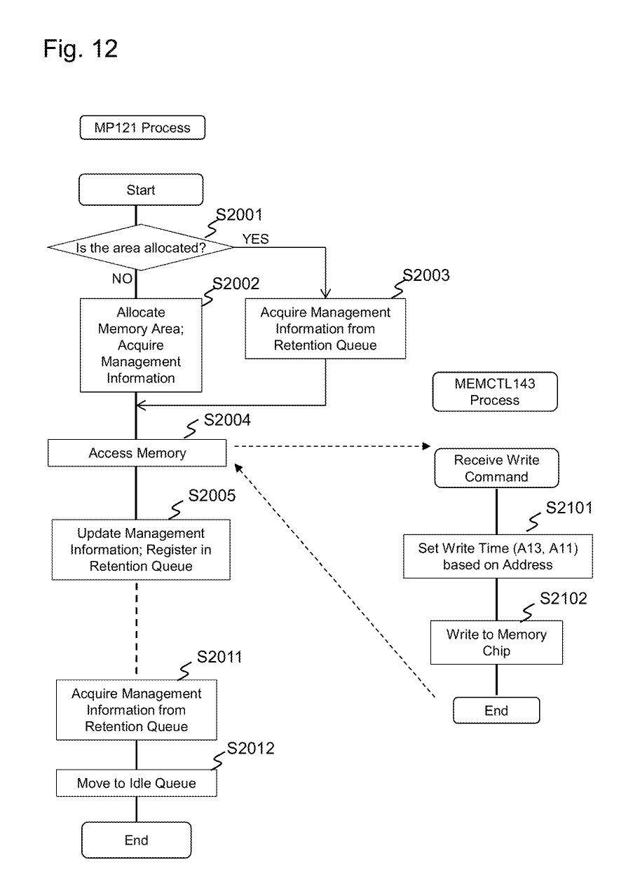

Next, the flow of processing when the MP 141 writes data in the memory area of the memory chip 144 will be described with reference to FIG. 12. In the storage system 10 of the present embodiment, when data is written in a memory area (slot), an unused slot (connected to the retention idle queue) is first selected and connected to the retention queue. This process may be referred to as a “slot allocation process.” In the event that the allocated slot becomes unnecessary, the slot may be removed from the retention queue and returned to the retention idle queue. This process may be referred to as a “slot release process.” Cases in which a memory area becomes unnecessary, for example, may include situations in which a memory area was being used as a cache area for storing write data from the host 2, but the data is written to drive 121, and as such it is no longer necessary to retain the data in a memory area. FIG. 12 is a diagram for primarily describing the process of allocating and releasing memory areas (slots) performed by the I/O program executed by the MP 141.

When the I/O program writes data to a slot, the MP 141 first determines whether the slot of the data write destination has been allocated (S2001). In this determination, when data to be written by the I/O program to a previously allocated slot, it may be determined that the slot is allocated. Also in this case, the I/O program may have already acquired the slot# 801 (or the memory address 802) of the slot to which the data is to be written. In contrast, if the I/O program writes to a slot that has not already been allocated, it is determined that the slot is not allocated.

If the slot has already been allocated, the I/O program may acquire the slot management information of the data write destination slot from the retention queue (S2003). In S2003, it is possible for the I/O program to search/acquire the slot management information of the data write destination slot by referring to the slot# 801 (or the memory address 802) of the data write destination slots it contains. At this time, the slot management information to be acquired is removed from the retention queue. In the event that the slot has not yet been allocated, the I/O program may allocate the slot by acquiring the slot management information from the retention empty queue (S2002). Also, at this time, a process to remove the slot management information to be acquired from the retention idle queue may be performed.

When allocating the slot of S2002, the determination regarding which slot of the four types of retention idle queues (short-retention idle queue, standard-retention idle queue, medium-retention idle queue, long-retention idle queue) from which to acquire the slot management information 800 may be decided based on the type and characteristics of the stored data by a program executed by the MP 141 (an I/O program in this example). For example, information regarding the type of data stored in the short-retention slot, the type of data stored in the standard-retention slot, the type of data stored in the medium-intention slot, or data stored in the long-retention slot may be embedded in the program in advance, and the program may determine the slot for the data storage destination based on this information. Alternatively, the program may continuously monitor the update frequency of each type of data, and perform control operations to store data with the highest update frequency in the short retention slot and store data with the lowest update frequency in the long-retention slot.

Next, in S2004, the I/O program may issue an access request to the allocated slot with respect to the CMPK 114. As the access request in this case is a write instruction, the write instruction and the write data may be transmitted to the I/O unit 302 of the CMPK 114. It should be noted that there are cases where the MP 141 (I/O program) directly transmits a write instruction and write data to the CMPK 114 as well as cases when a component other than the MP 141 transmits the write instruction and the write data to the CMPK 114. For example, when the storage system 10 receives write data from the host 2, the write data may be transmitted from the FE I/F 112 to the CMPK 114 without passing through the MPB 111. In such a case, the MP 141 may instruct the DMAC of the FE I/F 112 to transfer data from the FE I/F 12 to the CMPK 114. Upon receiving the instruction, the DMAC of the FE I/F 112 may transmit the write instruction and the write data to the CMPK 114.

The write destination address (write address) of the write data may be determined by the I/O program. When the size of the write data is the same as the size of the slot, a write address may be uniquely determined. In particular, the memory address 802 recorded in the slot management information 800 of the slot to be written to may become the leading write destination address of the write data.

When the size of the write data is smaller than the size of the slot, the I/O program may arbitrarily determine the write address. For example, when the size of the slot is 1 MB, it is possible to write data in an arbitrary area within a 1 MB range starting from the address stored in the memory address 802 of the slot management information 800 of the areas within the write destination slot. The I/O program may decide which address within this range the write data is to be written. Also, a plurality of sets of data may be stored in one slot. However, when storing a plurality of sets of data in one slot, it may be desirable to store data having the same (or similar) type (or characteristics).

In the I/O unit 302, the state of the signal to be input to the A13 pin and the A11 pin may be determined based on the address included in the write instruction (S2101). Subsequently, a write command WT may be issued to the memory chip 144 (S2102). At this time, the I/O unit may set the states of the A13 pin and the A11 pin to the state determined in S2101 and issue the write command WT.

After S2004, the I/O program may modify the last update time 803 of the slot management information 800 to the current time, and connect it to the tail end of the retention queue (S2005). This completes the data write process in the slot. Note that the matter of which retention queue the slot management information should be connected to may depend on which retention idle queue the slot management information 800 was originally connected. If the slot management information 800 is first connected to the standard-retention idle queue (prior to execution of S2002) the I/O program may connect the slot management information 800 to the end of the standard-retention queue in S2005.

After using the slot for a time, if the slot becomes unnecessary, the I/O program may perform a slot release process. In step S2011, the I/O program may acquire the slot management information 800 of the slot to be released from the retention queue (removed from the retention queue). Subsequently, the I/O program may connect the slot management information 800 to the retention idle queue (S2012), and the slot release process terminates. When the I/O program connects the slot management information 800 to the retention idle queue, the slot management information 800 is connected to the retention idle queue in which it originally existed. For example, after using the slot management information 800 connected to the short-retention idle queue, when returning (connecting) to the retention idle queue again, the I/O program returns the slot management information 800 to the short-retention idle queue.

Although an example in which the I/O program allocates and releases slots has been described above, configurations in which other programs allocate and release the slots described with reference to FIG. 12 are also possible. Fundamentally, in the storage system 10 of the present embodiment, programs using slots operate in accordance with the rule of allocating slots and performing memory access, and releasing slots when the slots become unnecessary. Accordingly, memory areas (slots) in use by the storage system 10 may be connected to the retention queue, and unnecessary (unused) slots may be connected to the retention idle queue.

### (2-3) Data Verification Process

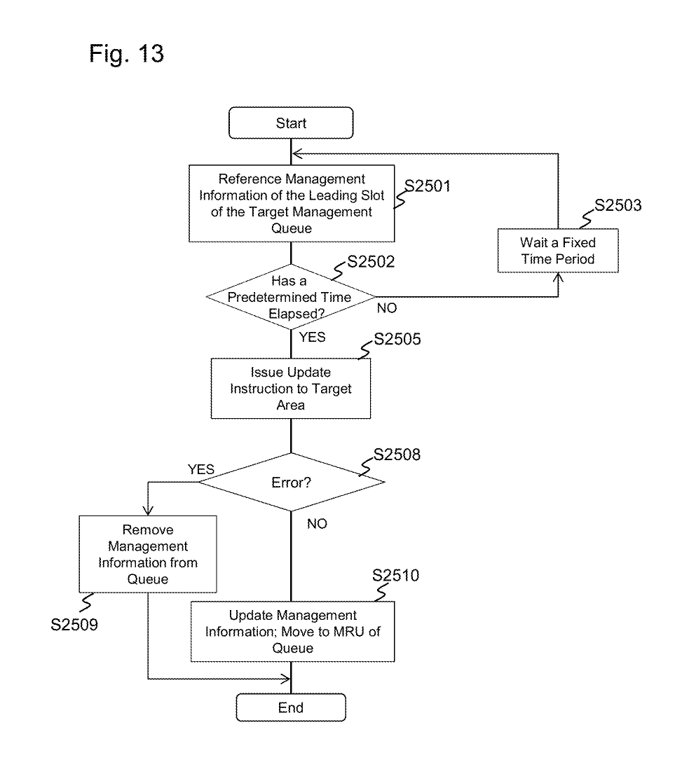

Next, the flow of a data verification process by a data verification program will be described with respect to FIG. 13. In the storage system 10 according to the present embodiment, data verification program may be executed for each retention queue. Also, with respect to the storage system 10 of the present embodiment, as four types of retention queues are provided, four data verification programs may be executed in parallel. In addition, each verification program may be executed periodically.

Hereinafter, the flow of processing executed by a particular data to verification program, for example a data verification program for performing data verification processing of the short-retention queue, will be described. Initially, the data verification program may designate the slot management information 800 (the slot management information 800 connected to the LRU pointer 852) located at the head of the short-retention queue (S2501). Hereinafter, the slot managed by the slot management information 800 designated herein may be referred to as a “target process slot”.

Subsequently, the data verification program may be configured to compare the last update time 803 of the designated slot management information 800 with the current time, and determine whether or not a period of time has passed once the last update time 803 that is greater than or equal to a predetermined time (S2502). If the elapsed time since the last update time 803 is shorter than the predetermined time (S2502: NO), the data verification program may wait for a fixed time period (S2503). After waiting for the fixed time period, the process may be executed again from S2501.

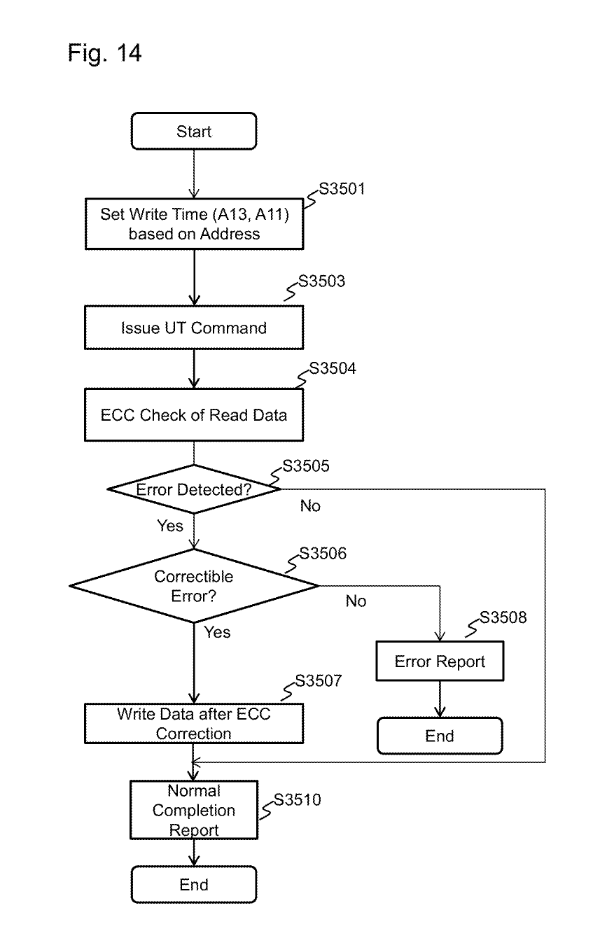

In the event that the time elapsed from the last update time 803 of the determined slot management information is greater than or equal to the predetermined time (S2502: YES), the data verification program may issue an update instruction to the target process slot (S2505). It should be noted that the update instruction may include an address range of the update destination (the address range may be designated, for example, using a start address and a data length, or using a set of start addresses and an end address). The address range included in the update instruction may designate an area of 1 MB (size of the slot) starting with the memory address included in the slot management information 800 of the target process slot. The I/O unit 302, having received the update instruction, may determine the state of the signal to be input to the A13 pin and the A11 pin based on the address included in the instruction similarly to step S2004, and subsequently issue the update command to the memory chip 144. The process performed by the I/O unit 302 may be described later (FIG. 14).

After issuing of the update command, an error may be returned from the CMPK 114. When an error is returned from the CMPK 114 (S2508: YES), the data verification program may remove the slot management information 800 of the target process slot from the short-retention queue, connect it to the error queue (S2509), and end the process. When a response indicating normal termination is returned from the CMPK 114 (S2508: NO), the data verification program may update the last update time 803 included in the slot management information 800 of the target process slot to the current time. Subsequently, the data verification program may connect the slot management information 800 to the tail end of the short-retention queue (S2510), and end the data verification process. The data verification program may be activated again after a fixed time period, and the processing may start from S2501.

In addition the process of FIG. 13 may be executed for other queues similarly to the process for the short-retention queue. However, the threshold value for the predetermined time used in the determination in S2502 and the standby time of S2503 may be different for each retention queue. The data retention time of slots managed by the short-retention queue may be short, as the data was written with a short write operation time. As such, it may be desirable that the data verification program that performs processing for slots managed by the short-retention queue be configured to set the threshold value for the predetermined time used in the determination in S2502 and the standby time of S2503 to also be substantially short. In contrast, as the information retention time of slots managed by the long-retention queue are long, it may be desirable that the data verification program that performs processing for slots managed by the long-retention queue be configured to set the threshold value for the predetermined time used in the determination in S2502 and the standby time of S2503 to be substantially long.

Next, a flow of processing performed by the CMPK 114 that received the update instruction will be described with reference to FIG. 14. The process in FIG. 14 may be performed by the I/O unit 302.

As in S2101, the I/O unit 302 may be configured to determine the state of the signal to be input to the A13 pin and the A11 pin based on the address included in the received update instruction (S3501). The I/O unit 302 may then issue an update command UT to the memory chip 144 (S3503).

In response to the update command, the memory chip 144 may read the data stored at the designated address, and return it to the I/O unit 302. In addition, the memory chip 144 may write the read data back to the same address (the designated address).

In response to receiving data from the memory chip 144, the I/O unit 302 may perform an ECC check of the received data (S3504). In the event that no error is detected as a result of the ECC check (S3505: NO), the I/O unit 302 responds to the MPU 141, which is the issuing source of the update instruction, that the updating process has ended normally, and subsequently terminates the process (S3510). In the storage system 10 of the present embodiment, the MP 141 may issue an update instruction to the CMPK 114 for the purpose of writing data back to the memory chip 144. In S3510, the I/O unit 302 may not return the data read from the memory chip 144 to the issuing source of the update instruction (MP 141 or the like). This is because, when the MP 141 issues an update instruction, data read from the memory chip 144 is not necessary.

In the event that an error detected (S3505: YES), the I/O unit 302 may determine whether the error is a correctable error (S3506). If the error is a correctable error (S3506: YES), the I/O unit 302 may correct the data read using the ECC and write the corrected data back to the memory chip 144 (S3507). The signal state determined in S3501 may be used as the signal input to the A13 pin and the A11 pin at this time. Alternatively, as another embodiment, the state of (A13, A11)=(H,H) may be used in order to suppress the probability of error occurrence. After the data is written back, the process may be terminated.

If the error is not a correctable error (S3506: NO; that is, it is an un-correctible error), data correction using the ECC cannot be performed. As such, the I/O unit 302 may report to the MPU 141 that issued the update instruction that an error has occurred (S3508) and ends the process.

### (2-4) Planned Stop Process

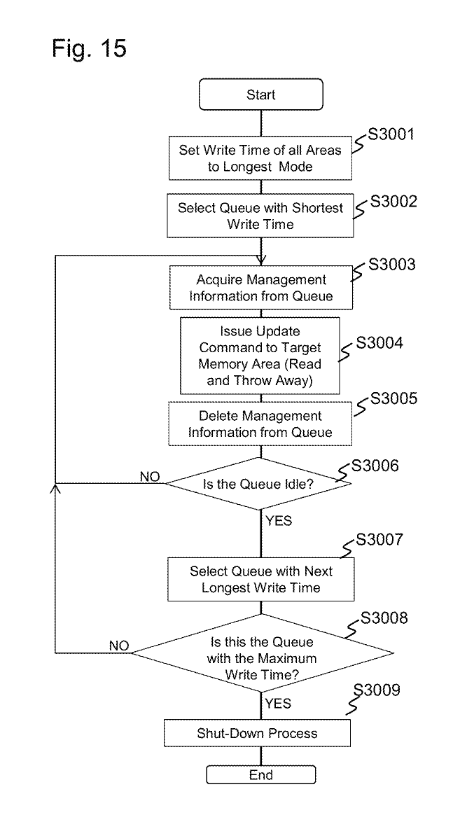

Next, the flow of processing performed with respect to the CMPK 114 when the storage system 10 of the present embodiment performs a scheduled shutdown will be described with reference to FIG. 15. When the storage system 10 is instructed to stop by the management terminal 7 or the like, a stop program may be executed in the MP 141. Hereinafter, the flow of processing executed by the stop program will be described.

First, the stop program may notify the CMPK 114 of the state of the signal to be input to the A13 pin and the A11 pin when writing data to the memory chip 141 (S3001). More particularly, the stop program may notify the CMPK 114 to configure the signals to be input to the A13 pin and the A11 pin to be (H,H) at the time of data writing for the entire area of the memory chip 144.

Next, the stop program may select queue for managing the slot with the shortest write operation time; that is, a short-retention queue may be selected (S3002), and one set of slot management information 800 connected to the queue may be taken out (S3003). Next, the stop program may issue an update instruction to the slot designated by the slot management information 800 retrieved in S3003 (S3004). In this way, an update command UT may be issued to the area of the memory chip 144 corresponding to this slot, and the update process may be performed.

Subsequently, the stop program may delete the slot management information from the retention queue (S3005). The processes of S3003 to S3005 may be repeated until no slot management information 800 remains connected to the retention queue (S3006).

In step S3007, the stop program may select a queue for managing the slot having the next shortest write operation time. If the queue selected in S3007 is a long-retention queue (S3008: YES), the MP 141 may stop the storage system 10 (S3009). If the queue selected in S3007 is not a long-retention queue (S3008: NO), the MP 141 may repeat the process from S3003.

In the above description, an example in which the update process is not performed for slots managed by long-retention queues is described. This is because, as the write operation time at normal writing times for slots managed by long-retention queues is long, the information retention time is long and the need to perform update processing is lower than for slots managed by other retention queues. However, configurations in which update processes may also be performed for slots managed by long-retention queues are also possible. Embodiments in which update processing is not performed on slots managed by either long-retention queues or slots managed by medium-retention queues are also possible.

Hereinabove, a description of the storage system according to the present embodiment was provided. The storage system 10 according to the present embodiment may perform management by dividing the area of the memory chip 144 (e.g., slot) into an area (referred to as area A) in which data is written with a write operation time A at data write time an area (referred to as area 10 in which data is written with a write operation time B at data write time, an area (referred to as area C) in which data is written with a write operation time C at data write time, and an area (referred to as area D) in which data is written with a write operation time D at data write time (according to the relationship A<B<C<D). When the MP 141 (or DMAC) of the storage controller 11 writes data to the memory chip 144, one of the regions A to D may be selected based on the type and characteristics of the data to be written, and the data may be written to the selected area. Upon receiving the data write instruction, the CMPK 114 may determine the write operation time based on the address of the target write area, and write the data to the memory chip 144. In order to perform such operations, the storage system 10 may select a write operation time for writing data in the memory chip 144 based on the type and characteristics of the data to be written.

If the write operation time is made longer when writing data to the memory chip 144, the information retention time may be lengthened. However, it the write operation time is long, the write processing time may also be prolonged, such that access performance is impacted. Conversely, if the write operation time is short, access performance may be improved, but the information retention period may be reduced. In the storage system of the present embodiment, the write operation time may be determined according to the type and characteristics of the data to be written, such that, for example, writing may be performed with long write operation times only when the data to be written requires long-term storage. Accordingly, access performance maintenance and improvement can be achieved together with data loss prevention.

In addition, in the storage system 10 of the present embodiment, as the area of the memory chip 144 is periodically updated, it is possible to prevent information loss. Also, at the time of updating, update processing is not performed for all areas of the memory chip 144, but only for slots managed by retention queues; that is, slots being used by the storage system 10. As such, the update process may be omitted for slots that are not being used (e.g., as necessary data is not stored), such that it may be possible to improve the efficiency of the updating process.

Also, in the storage system 10 of the present embodiment, areas of the memory chip 144 can be updated even at a planned stop time. As it cannot be expected for writes to be performed to memory chip 144 areas during the stop period, an update process with a longer write operation time may be performed. As a result, it may be possible to prevent information stored in the memory chip 144 from being lost even when updates are not performed for a relatively long period. When performing the update process, the update process may be performed only for slots managed by the retention queue (slots being used by the storage system 10). As such, the update process may be omitted for slots that are not being used (e.g., as necessary data is not stored), such that it may be possible to improve the efficiency of the updating process.

Also, in the update process of the storage system according to the present embodiment, the memory chip that has received the update instruction may read the data designated by the update instruction from a memory element (memory cell) and write the data back to the memory element, the read data may be transmitted to the memory controller, and the memory controller may perform an ECC check. When an error is detected as the result of the ECC check, the memory controller may perform data correction and write the corrected data back to the memory chip. When no errors are detected by the ECC check, as it not necessary for the memory controller to write the data back to the memory chip, the update process can be efficiently performed.

Although an example of the above-described embodiment was provided in which the write operation time is determined when performing a write process or an update process to an area of the memory chip 144 based on the write (or update) target address on the memory chip 144, the method of designating the write operation time is not limited to the aspects described above. For example, even in a configuration in which information specifying the write operation time is included in a write instruction or update instruction issued from the MP 141 to the CMPK 114, and the CMPK 114 modifies the state of the input signal to pin A13 and pin A11 of the memory chip 144 at write time based on the information specifying the write operation time included in the instructions, the write operation time can be designated based on the type and characteristics of the data to be written.

Also, in the present embodiment, when a program (I/O program or the like) executed by the MP 141 allocated an area (slot) of the memory chip 144, a slot is acquired from one of the short-retention idle queue, the standard-retention idle queue, the medium-retention idle queue, or the long-retention idle queue based on the characteristics, type, usage, etc. of the data to be stored. In this method, for example, once a slot is acquired from the short-retention idle queue, the write operation time when writing information to this slot is not changed. Accordingly, as another embodiment, configurations in which the write operation time may be dynamically changed at information write time according to the access frequency of data stored in the slot are also possible.

For example, the write frequency information may be managed as part of the slot management information. Each time data is written to a slot, the program that executes the data write to the slot may update the write frequency information of the slot management information. Then, the MP 141 may periodically monitor the write frequency information of each slot, and perform control operations so that slots with high write frequencies are moved to the short-retention queue, and slots with low write frequencies are moved to the long-retention queue. For the slots managed by the short-retention queue, the MP 141 may perform control operations to write data using a short write operation time during the write process or the update process, and for those slots managed by the long-retention queue, data may be written using a long operation time. In this way, it may become possible to dynamically change the write operation time at data write time according to data characteristics such as write frequency.

Although embodiments of the present invention have been described herein, the aspects of the present invention are illustrated by way of example, and the scope of the present invention is not limited to these embodiments. That is, the present invention can be implemented in a variety of other forms.

For example, in the present embodiment, an example in which MRAM or STT-RAM is used as the memory chip 144 has been described, but other types of memories may be used. As examples, resistance random access memory (ReRAM), phase change memory (PCM), phase change random access memory (PRAM) or the like may be used.

### REFERENCE SIGNS LIST

2 Host
6 SAN
7 Management Terminal
10 Storage system
11 Storage Controller
12 Disk Unit
13 Battery
111 MPB
112 FE I/F
113 BE I/F
114 CMPK
115 Switch
141 MP
142 Memory
143 Memory Controller
144 Memory Chip

What is claimed is:

1. A storage system comprising:
a storage device; and
a storage controller including:
a memory chip with a magneto-resistive element as a memory element,
a memory device including a memory controller configured to control the memory chip, and
a processor;
wherein the processor is configured to:
manage a storage area of the memory chip by dividing the storage area into a storage area used by the processor and a storage area not used by the processor, and
execute, in a periodic fashion, an update process of reading data stored in the storage area used by the processor and writing the data back to the storage area.

2. The storage system according to claim 1, wherein:
the processor is configured to issue an update instruction for the storage area to the memory device when executing the update process for the storage area; and
the memory chip of the memory device that receives the update instruction is configured to read data stored in the storage area, return the data to the memory controller, and write the read data back to the storage area.

3. The storage system according to claim 2, wherein:
the memory controller is configured to:
receive, from the storage controller, both a write instruction and target write data,
generate an error correction code from the target write data, and
store, in the memory chip, the target write data to which the error correction code is attached.

4. The storage system according to claim 3, wherein:
the data returned to the memory controller includes the error correction code; and
the memory controller is configured to:
perform, in response to receiving the data from the memory chip, a data check using the error correction code,
correct, in response to detecting a correctible error as a result of the data check, the data, and
write the corrected data back to the memory chip.

5. The storage system according to claim 2, wherein:
the processor manages the storage area of the memory chip by dividing it into at least a first area and a second area based on an information retention time;
the memory device is configured to:
lengthen a writing time for storing data in the second area with respect to a writing time for storing data in the first area; and
select, when the processor stores data in the memory device, one of the first area or the second area based on characteristics of the data.

6. The storage system according to claim 5, wherein:
the memory device is configured to:
lengthen, in response to receiving the update instruction from the processor, a writing time for storing data in the second area with respect to a writing time for storing data in the first area.

7. The storage system according to claim 6, wherein:
the processor is configured to:
issue, with respect to the memory device in response to receiving a stop instruction of the storage system, an update instruction regarding the storage area used by the processor in the first area.

8. The storage system according to claim 7, wherein:
the memory device is configured to:
store, when storing data with respect to the first area, data in the first area by applying a current to the memory element constituting the first area for a time T0, and
write back, in response to the processor receiving the stop instruction, the data to the storage area used by the processor by applying a current to the memory element constituting the storage area used by the processor for a period of time T1 greater than T0.

9. The storage system according to claim 2, wherein:
the memory controller is configured to:
designate, when instructing a data write to the memory chip or when instructing a data update to the memory chip, a current application time for the memory element.

10. The storage system according to claim 9, wherein:
the memory chip is configured to write data to the memory element by applying a current to the memory element according to the current application time designated by the memory controller.

11. A method for controlling a storage system including:
a storage device; and
a storage controller having a memory chip with a magneto-resistive element as a memory element, a memory device including a memory controller configured to control the memory chip, and a processor; the method comprising:
managing, using the processor, a storage area of the memory chip by dividing the storage area into a storage area used by the processor and a storage area not used by the processor, and
executing, by the processor in a periodic fashion, an update process of reading data stored in the storage area used by the processor and writing the data back to the storage area.

12. The method according to claim 11, further comprising:
issuing, by the processor when executing the update process for the storage area, an update instruction for the storage area to the memory device;
reading, by the memory chip of the memory device, the data stored in the storage area;
returning, by the memory chip of the memory device, the data to the memory controller; and
writing, by the memory chip of the memory device, the read data back to the storage area.

13. The method according to claim 12, further comprising:
managing, by the processor, the storage area of the memory chip by dividing it into at least a first area and a second area based on an information retention time;
lengthening, by the memory device, a writing time for storing data in the second area with respect to a writing time for storing data in the first area; and
selecting, by the memory device when the processor stores data in the memory device, one of the first area or the second area based on characteristics of the data.

14. The method according to claim 13, further comprising:
lengthening, by the memory device in response to receiving the update instruction from the processor, a writing time for storing data in the second area with respect to a writing time for storing data in the first area.

15. The method according to claim 14, further comprising:
issuing, by the processor with respect to the memory device when stopping the storage system, an update instruction regarding the storage area used by the processor in the first area.
